(19) United States
(12) Patent Application Publication
(10) Pub. No.: US 2007/0077726 A1
(43) Pub. Date: Apr. 5, 2007

(54) Semiconductor device and fabrication method therefor

(76) Inventors: Masavuki Moriva, Fukushima-ken (JP); Takavuki Enda, Fukushima-ken (JP)

Correspondence Address: WAGNER, MURABITO & HAO LLP, Third Floor, Two North Market Street, San Jose, CA, 95113, US

(21) Appl. No.: 11/529,805

(22) Filed: Sep. 29, 2006

Related U.S. Application Data
(63) Continuation-in-part of application No. PCT/JP05/18105, filed on Sep. 30, 2005.

(51) Int. Cl. H01L 21/76; H01L 31/112; H01L 29/80; H01L 31/0288

(52) U.S. Cl. 438/435; 257/257

(57) ABSTRACT

The present invention provides a method of fabricating a semiconductor device including forming an insulation film on or above a semiconductor substrate, forming contact holes in the insulation film, forming a metal layer in the contact hole, polishing an upper portion of the insulation film below a top surface of an upper portion of the metal layer, and polishing the upper portion of the metal layer. It is possible to provide a semiconductor device in which the size of the contact hole and the distance therebetween can be reduced and a fabrication method therefor.

### CROSS-REFERENCES TO RELATED APPLICATIONS

This is a continuation in part of International Application No. PCT/JP2005/018105, filed Sep. 30, 2005 which was not published in English under PCT Article 21(2).

### TECHNICAL FIELD

This invention relates generally to semiconductors and fabrication methods therefor, and more particularly, to a semiconductor device having an interlayer insulation film with contact holes therein and a fabrication method therefor.

### BACKGROUND

In order to improve the performance and reduce the costs of the semiconductor devices, the development is in progress to decrease the sizes of the layout rule. To decrease the sizes of the layout rule of the wiring layer, there is a demand for decreasing the sizes of the contact holes formed in the interlayer insulation film and the distances therebetween. The contact hole has a plug metal formed therein, and electrically couples the lower layer wiring (alternatively, the semiconductor substrate) and the upper layer wiring.

A description will now be given of a conventional method of forming the contact holes. Firstly, conventional example 1 disclosed in Japanese Patent Application Publication No. 9-326436 will be described, with reference to FIG. 1A (PRIOR ART) through FIG. 1C (PRIOR ART). Referring to FIG. 1A (PRIOR ART), an interlayer insulation film 12 made, for example, of a silicon oxide film is formed on or above a semiconductor substrate 10. Contact holes 14a are formed in the interlayer insulation film 12. Referring to FIG. 1B (PRIOR ART), a tungsten film 16a is provided in the contact holes 14a and in the interlayer insulation film. FIG. 1B (PRIOR ART) is a view showing the process of the formation. Referring to FIG. 1C (PRIOR ART), a tungsten film 16b is formed in the contact holes 14a and on the interlayer insulation film 12.

Next, conventional example 2 disclosed in Japanese Patent Application Publication No. 10-199977 will be described, with reference to FIG. 2A (PRIOR ART) and FIG. 2B (PRIOR ART). Referring to FIG. 2A (PRIOR ART), the interlayer insulation film 12 is formed on or above the semiconductor substrate 10. Contact holes 14 are formed in the interlayer insulation film 12. At this time, the contact holes 14 are formed in such a manner that openings arranged in the upper portion are wider than the lower portion of the contact holes 14. Referring to FIG. 2B (PRIOR ART), a tungsten film 16 is provided in the contact holes 14 and on the interlayer insulation film 12. Referring to FIG. 2C (PRIOR ART), the tungsten film 16 is polished by Chemical Mechanical Polishing (CMP) to the top surface of the interlayer insulation film 12. This forms plug metals 18 embedded in the contact holes 14. Subsequently, an upper wiring layer (not shown) is formed to be connected to the plug metals 18. In this manner, the contact holes 14 and the plug metals 18 are provided. Here, a description has been given of a case where the contact holes 14 and 14a are in connection with the semiconductor substrate 10 in the conventional example 1 and conventional example 2. Similarly, there is also a case where the contact holes 14 and 14a are in connection with a lower wiring layer.

Also, Japanese Patent Application Publication No. 2004-146582, Japanese Patent Application Publication No. 2004-228519, and Japanese Patent Application Publication No. 2001-85373 disclose a polishing method in which a silicon nitride film serves as a polishing stopper layer with the use of an abrasive agent that includes cerium oxide also known as ceria slurry as abrasive particles.

In the conventional example 1, if the sizes of the contact holes 14a are decreased, a blockage occurs in the tungsten film 16a in the upper portion of the contact holes 14a. This is because the tungsten film 16a is easily grown in the upper portion of the contact holes 14a. This results in the impedance of the growth of the tungsten film 16b in the contact holes 14a, generating voids 15 in the tungsten films 16b inside the contact holes 14a. The voids 15 may increase electric resistance or cause a disconnection of the plug metals 18 in the contact holes 14a.

In the conventional example 2, as shown in FIG. 2A (PRIOR ART), since the openings are wider in the upper portion of the contact holes 14, it is possible to delay the blockage of the tungsten film 16 in this part. Thus, as shown in FIG. 2B (PRIOR ART), it is possible to suppress the generation of the voids of the tungsten film 16 in the contact holes 14. As shown in FIG. 2C (PRIOR ART), however, if the distances between the contact holes 14 are smaller, the distances between the interlayer insulation film 12 arranged between the plug metals 18 become extremely small in the upper portion of the interlayer insulation film 12. As a result, a short circuit may occur between the plug metals 18.

As described, in accordance with the reduction in size of the contact hole 14 and the reduction in distance therebetween, the electric resistance of the plug metal 18 in the contact hole 14 and disconnection may be increased, or a short circuit between the plug metals 18 may occur. For these reasons, there are drawbacks in that it is difficult to reduce the size of the contact hole and the distances therebetween.

### SUMMARY OF THE INVENTION

The present invention provides a semiconductor device in which the size of the contact hole and the distance therebetween can be reduced and a fabrication method therefor.

In accordance with one particular embodiment of the present invention, there is provided a method of fabricating a semiconductor device including: forming an insulation film on or above a semiconductor substrate; forming contact holes in the insulation film; forming a metal layer in the contact holes; polishing an upper portion of the insulation film below a top surface of an upper portion of the metal layer; and polishing the upper portion of the metal layer. It is possible to provide a fabrication method of the semiconductor device in which the size of the contact hole and the distance therebetween can be reduced.

In accordance with one particular embodiment of the present invention, there is provided a method of fabricating a semiconductor device including: forming an interlayer insulation film on or above a semiconductor substrate; forming contact holes so that the contact holes in an upper portion of the interlayer insulation film is wider than the contact holes in a lower portion of the interlayer insulation film; forming a metal layer in the contact holes; and polishing the upper portion of the interlayer insulation film and the metal layer, the upper portion being wider than the other portion of the contact holes. It is possible to provide a fabrication method of the semiconductor device in which the size of the contact hole and the distance therebetween can be reduced.

In accordance with one particular embodiment of the present invention, there is provided a semiconductor device including: an interlayer insulation film provided on or above a semiconductor substrate; a silicon oxy-nitride film provided on or above the interlayer insulation film; and a metal layer provided in contact holes formed in the interlayer insulation film, and having a top surface substantially coplanar with a top surface of the silicon oxy-nitride film. It is possible to provide a semiconductor device in which the size of the contact hole and the distance therebetween can be reduced.

### BRIEF DESCRIPTION OF THE DRAWINGS

(PRIOR ART) FIG. 1A, FIG. 1B, and FIG. 1C are cross-sectional views of a fabrication process of a semiconductor device of conventional example 1;

(PRIOR ART) FIG. 2A, FIG. 2B, and FIG. 2C are cross-sectional views of the fabrication process of the semiconductor device of conventional example 2;

FIG. 3A, FIG. 3B, FIG. 3C, and FIG. 3D are first cross-sectional views of the fabrication process of the semiconductor device in accordance with a first embodiment of the present invention;

FIG. 4A, FIG. 4B, and FIG. 4C are second cross-sectional views of the fabrication process of the semiconductor device in accordance with the first embodiment of the present invention;

FIG. 5 is a cross-sectional view of the semiconductor device in accordance with a variation example of the first embodiment;

FIG. 6A, FIG. 6B, FIG. 6C, and FIG. 6D are third cross-sectional views of the fabrication process of the semiconductor device in accordance with the first embodiment of the present invention;

FIG. 7A, FIG. 7B, and FIG. 7C are first cross-sectional views of the fabrication process of the semiconductor device in accordance with a second embodiment of the present invention;

FIG. 8A, FIG. 8B, FIG. 8C, and FIG. 8D are second cross-sectional views of the fabrication process of the semiconductor device in accordance with the second embodiment of the present invention; and

FIG. 9 is a view showing polishing rates of insulation films.

FIG. 10 illustrates a block diagram of a portable phone, upon which embodiments can be implemented.

FIG. 11 illustrates a block diagram of a computing device, upon which embodiments of the present claimed subject matter can be implemented.

FIG. 12 illustrates an exemplary portable multimedia device, or media player, in accordance with an embodiment of the present claimed subject matter.

FIG. 13 illustrates an exemplary digital camera, in accordance with an embodiment of the present claimed subject matter.

### DETAILED DESCRIPTION

Reference will now be made in detail to embodiments of the present claimed subject matter, examples of which are illustrated in the accompanying drawings. While the claimed subject matter will be described in conjunction with these embodiments, it will be understood that they are not intended to limit the claimed subject matter to these embodiments. On the contrary, the claimed subject matter is intended to cover alternatives, modifications and equivalents, which may be included within the spirit and scope of the claimed subject matter as defined by the appended claims. Furthermore, in the following detailed description of the present claimed subject matter, numerous specific details are set forth in order to provide a thorough understanding of the present claimed subject matter. However, it will be evident to one of ordinary skill in the art that the present claimed subject matter may be practiced without these specific details. In other instances, well known methods, procedures, components, and circuits have not been described in detail as not to unnecessarily obscure aspects of the claimed subject matter.

### First Embodiment

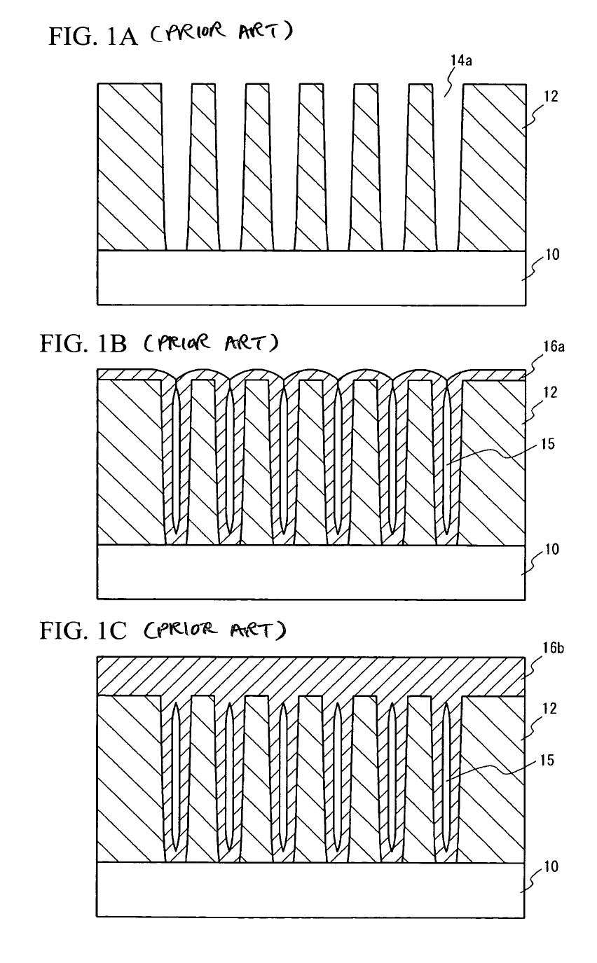

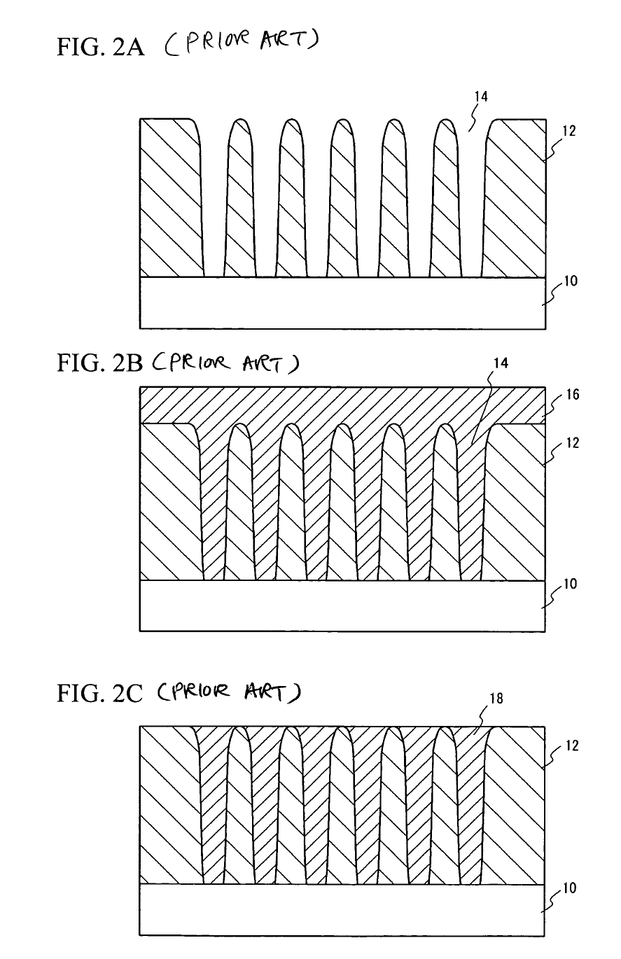

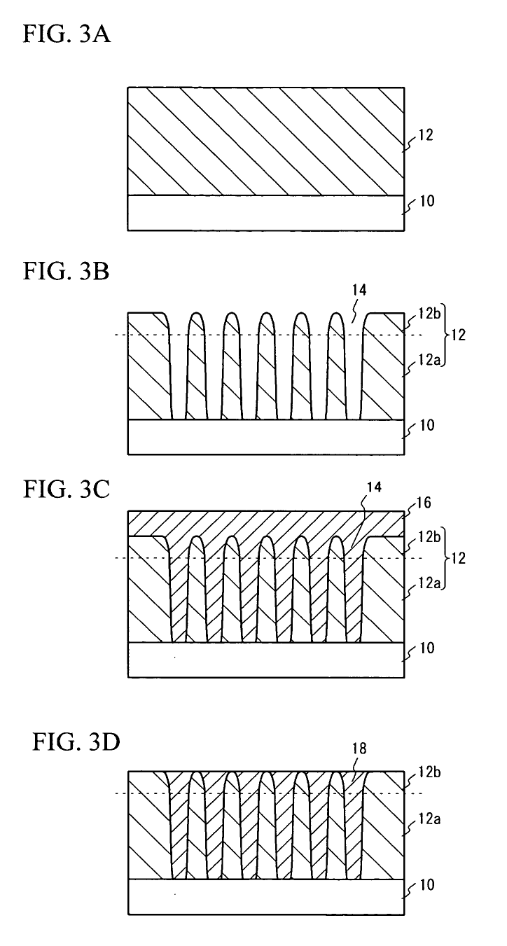

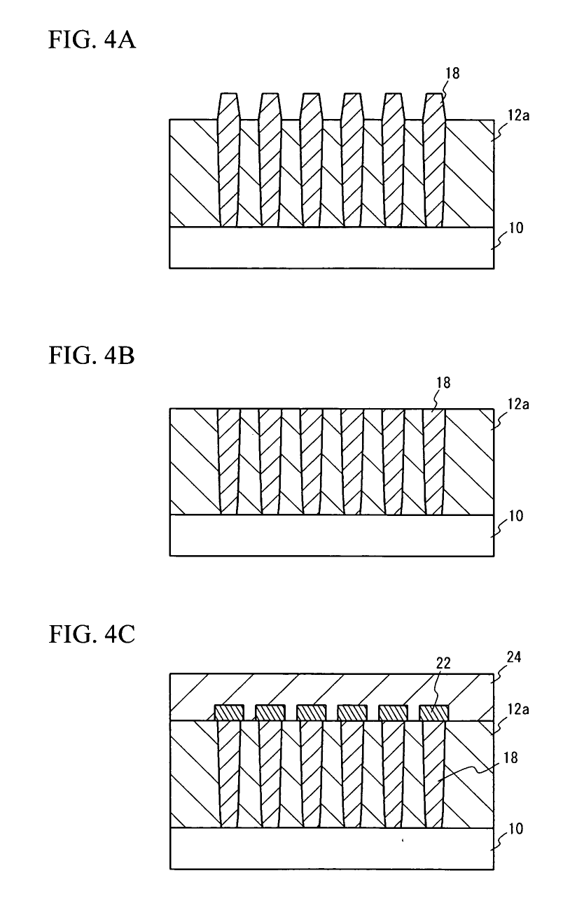

A first embodiment of the present invention will be described with reference to FIG. 3A through FIG. 4C. Referring to FIG. 3A, a silicon oxide film of, for example, 650 nm in thickness is deposited on or above a silicon semiconductor substrate 10 as an interlayer insulation film 12, by using, for example, tetraethylorthosilicate (TEOS). Referring to FIG. 3B, contact holes 14 are formed in the interlayer insulation film 12 to extend through the interlayer insulation film 12, by dry etching process. At this time, the contact holes 14 are formed in such a manner that the contact holes 14 in an upper insulation film 12b (in an upper portion of an insulation film) of the interlayer insulation film 12 are wider than those in a lower insulation film 12a (in a lower portion of the insulation film) of the interlayer insulation film 12 and openings are gradually wider upwardly.

Referring to FIG. 3C, the tungsten film 16 (a layer to be a metal layer) is formed in the contact holes 14 and on the interlayer insulation film 12. Referring to FIG. 3D, the tungsten film 16 (the layer to be the metal layer) is polished to the interlayer insulation film 12 by CMP. This forms plug metals 18 (metal layer) embedded in the contact holes 14 in the interlayer insulation film 12.

Referring to FIG. 4A, for example, 50 nm of the upper insulation film 12b of the interlayer insulation film 12 is polished by CMP. At this time, by increasing the density of the abrasive agent, reducing the add amount of oxidizing agent (hydrogen peroxide solution), and performing the mechanical polishing, the upper insulation film 12b is selectively polished, although the plug metals 18 are hardly polished. By this, the plug metals 18 protruding from the lower interlayer insulation film 12a remain. Referring to FIG. 4B, the plug metals 18 are polished to the lower interlayer insulation film 12a. Here, the plug metals 18 are selectively polished by reducing the density of the abrasive agent and adding a substantial amount of the oxidizing agent (hydrogen peroxide solution). This results in the surfaces of the plug metals 18 substantially coplanar with that of the lower interlayer insulation film 12a.

Referring to FIG. 4C, wiring layers 22 are formed on the lower interlayer insulation film 12a and on the plug metals 18 with the use of, for example, aluminum. On the wiring layers 22, formed is an upper layer interlayer insulation film or protection film 24 made, for example, of a silicon oxide film. As described, the wiring layer made of one layer is completed. Then, multilayer interconnection may be provided by forming the contact holes in the upper layer interlayer insulation film 24 in a similar manner and performing the process shown in FIG. 3A through FIG. 4C.

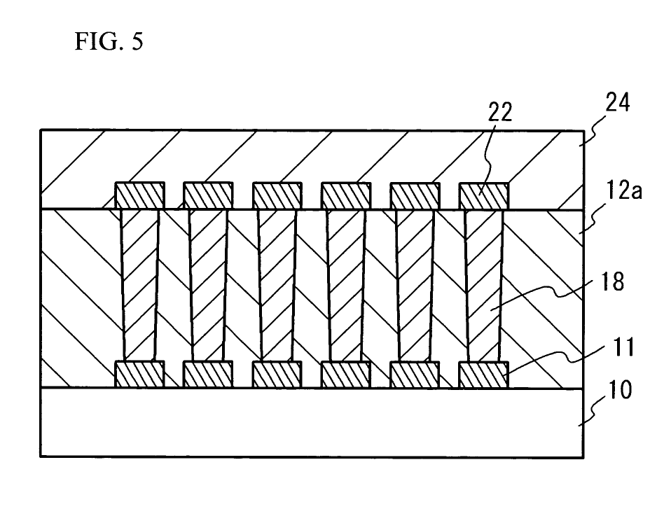

In FIG. 3D through FIG. 4C, the contact holes 14 are directly in connection with the semiconductor substrate 10. As shown in FIG. 5, however, the contact holes 14 may be connected to lower layer wiring layers 11.

In accordance with the first embodiment, as shown in FIG. 3B, the openings in the upper portion of the contact holes 14 are wider at the time of forming the tungsten film 16, thereby making it possible to suppress the voids in the tungsten film 16. As shown in FIG. 4A and FIG. 4B, the plug metals 18 (metal layer) and the contact holes 14 in the interlayer insulation film 12 (insulation film) are polished in the upper portion wider than the other portions. As a result, the distances of the openings in the upper part of the contact holes 14 are increased, thereby making it possible to suppress a short circuit between the contact holes 14. It is therefore possible to reduce the size of the contact hole and the distance therebetween.

In addition, the polishing rates are different between the interlayer insulation film made of an insulation film such as a silicon oxide or the like and the plug metal made of tungsten or the like. For this reason, the upper insulation film 12b of the interlayer insulation film 12, below the top surface of the upper portions of the plug metals 18, is selectively polished. Subsequently, the upper portions of the plug metals 18 (metal layer) are selectively polished. This makes it possible to planarize the surfaces of the plug metals 18 and that of the interlayer insulation film 12.

### Second Embodiment

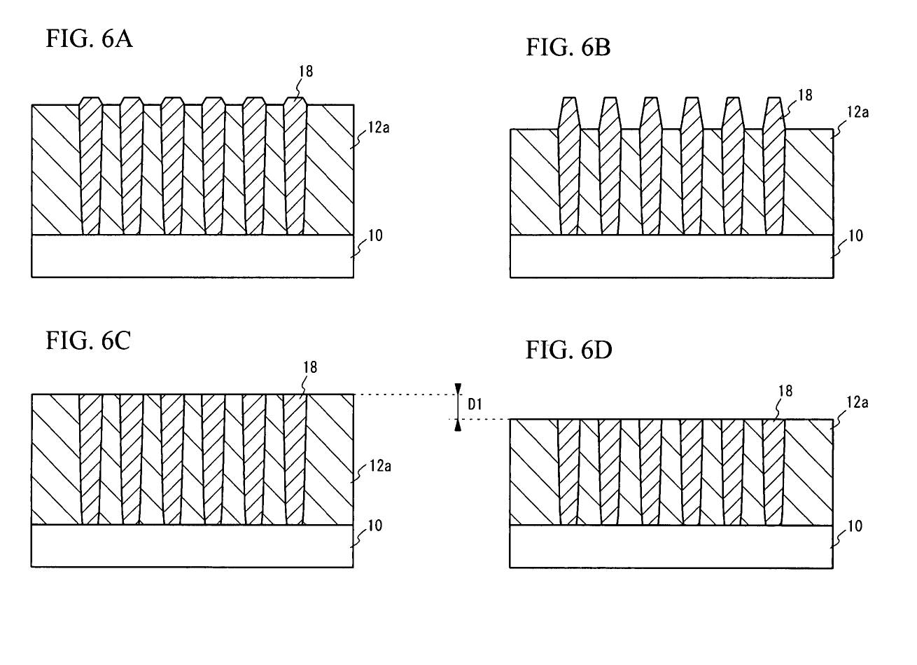

In the first embodiment, although the surfaces of the plug metals 18 and that of the interlayer insulation film 12 can be planarized, the film thickness of the lower interlayer insulation film 12a and those of the plug metals 18 are different in the wafer plane of the silicon semiconductor substrate 10, due to uneven polishing rates in the wafer plane or dishing. This is caused by the positions in the wafer and density of the plug metals. FIG. 6A through FIG. 6D are views explaining the above-described drawbacks. FIG. 6A and FIG. 6B, corresponding to FIG. 4A, are cross-sectional views of different positions in an identical wafer. The same components and configurations as those shown in FIG. 4A have the same reference numerals and a detailed explanation will be omitted. In FIG. 6B, the lower interlayer insulation film 12a is polished more than that shown in FIG. 6A. FIG. 6C and FIG. 6D are views in which the plug metals 18 are polished by CMP, subsequent to FIG. 6A and FIG. 6B in a similar manner as FIG. 4B. In FIG. 6D, the lower interlayer insulation film 12a and the plug metals 18 are thinner than those shown in FIG. 6C. In the first embodiment, D1, which is a thickness distribution of the lower interlayer insulation film 12a and the plug metals 18 in the wafer plane, is approximately 50 nm. As stated above, when the thickness distribution of the lower interlayer insulation film 12a and the plug metals 18 is large in the wafer plane, insulation properties differ in a longitudinal direction of the interlayer insulation film 12. Also, the focus is misaligned in the lithography, when the pattern in an upper layer is formed.

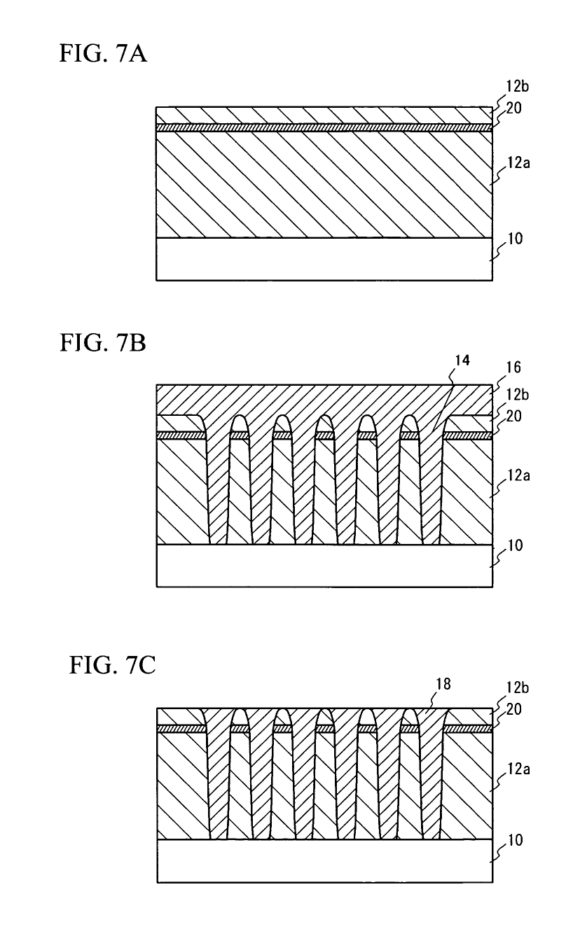

In the second embodiment, the above-described drawbacks are addressed. Referring to FIG. 7A, the lower interlayer insulation film 12a made, for example, of a silicon oxide film is provided on the silicon semiconductor substrate 10. A silicon oxy-nitride film or silicon nitride film is deposited on the lower interlayer insulation film 12a as a stopper layer 20 by Chemical Vapor Deposition (CVD). On the stopper layer 20, there is formed the upper insulation film 12b made, for example, of a silicon oxide film.

Referring to FIG. 7B, the contact holes 14 are formed to extend through the upper insulation film 12b, the stopper layer 20, and the lower interlayer insulation film 12a. At this time, the contact holes 14 are formed in such a manner that the contact holes 14 in the upper insulation film 12b are wider than those in lower interlayer insulation film 12a and the openings are gradually wider upwardly. Referring to FIG. 7C, the tungsten film 16 is polished to the top surface of the upper insulation film 12b by CMP.

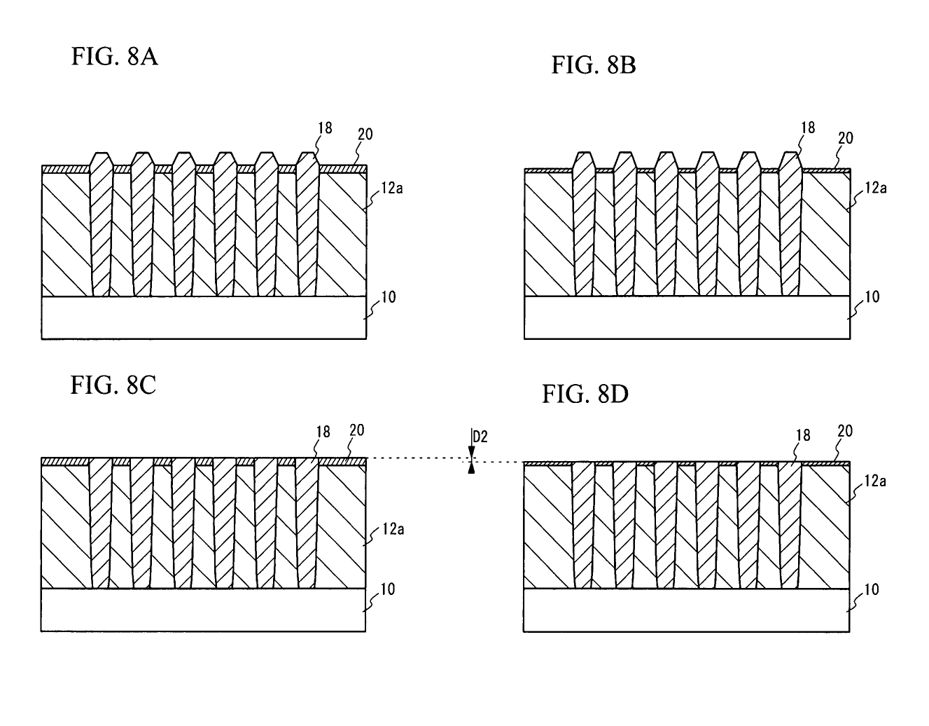

FIG. 8A and FIG. 8B show different positions in the wafer plane, similarly to FIG. 6A and FIG. 6B. Referring to FIG. 8A and FIG. 8B, the upper insulation film 12b is polished to the stopper layer 20 by CMP. At this time, since the polishing rate of the stopper layer 20 is slower than that of the upper insulation film 12b, the polishing stops at the stopper layer 20. FIG. 8C and FIG. 8D are views in which the plug metals 18 are polished to the stopper layer 20 by CMP, subsequent to the process shown in FIG. 8A and FIG. 8B. In FIG. 8D, the lower interlayer insulation film 12a and the plug metals 18 are thinner than those shown in FIG. 8C. However, when a silicon nitride film is used as the stopper layer in the second embodiment, D2, which is a thickness distribution of the lower interlayer insulation film 12a and the plug metals 18 in the wafer plane, is approximately 10 nm. In this manner, in a similar manner as in the first embodiment, the wiring layer 22 and the upper interlayer insulation film or protection film 24 are provided.

As described, the semiconductor device employed in the second embodiment, as shown in FIG. 8C, in which a silicon oxy-nitride film or silicon nitride film is used as the stopper layer 20, includes: the lower interlayer insulation film 12a (interlayer insulation film) 12a provided on the semiconductor substrate 10; the stopper layer 20 (oxy-nitride silicon film) provided on the lower interlayer insulation film 12a; and the plug metals 18 (metal layer) provided in the contact hole 14 formed in the lower interlayer insulation film 12a and having a surface substantially coplanar with the surface of the stopper layer 20 (oxy-nitride silicon film).

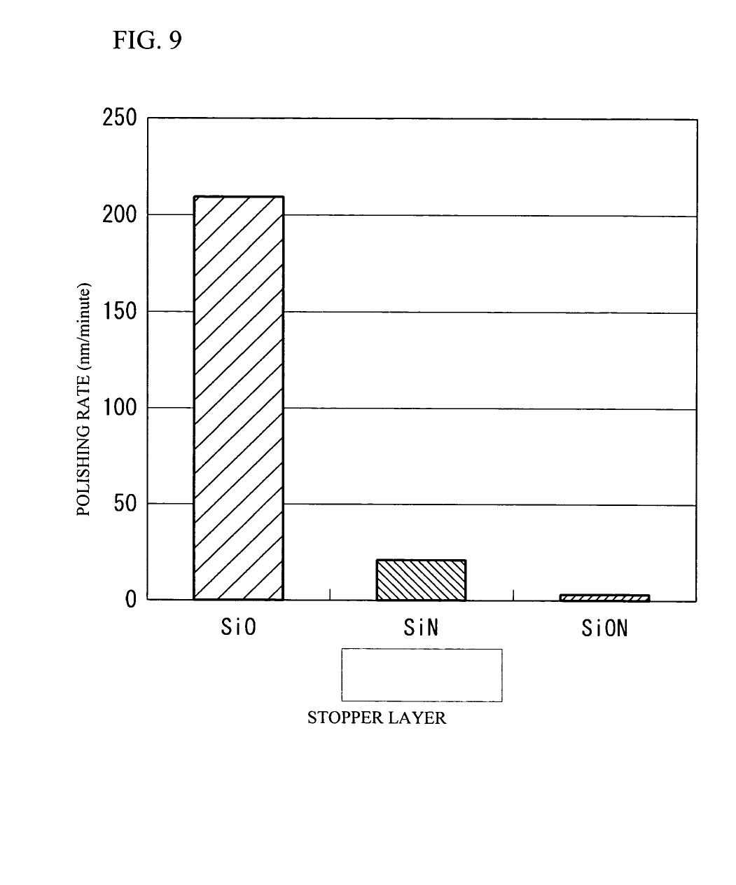

FIG. 9 is a view showing polishing rates when a silicon oxide film, a silicon nitride film, and a silicon oxy-nitride film are polished with the use of ceria slurry (CeO₂ abrasive particles) as an abrasive agent. Whereas the polishing rate of the silicon oxide film is approximately 210 nm/minute, the polishing rate of the silicon nitride film is approximately 21 nm/minute and that of the silicon oxy-nitride film is approximately 2.6 nm/minute. As described, the insulation film having nitrogen is small in the polishing rate, thereby making it possible to decrease the polishing rate of the silicon oxy-nitride film, in particular.

Accordingly, in the second embodiment, ceria slurry is employed as an abrasive agent to polish the silicon oxide film serving as the upper insulation film 12b, the silicon nitride film serving as the stopper layer 20, and the upper insulation film 12b and to polish the plug metals 18, thereby making it possible to make the thickness D2 of the lower interlayer insulation film 12a and the plug metals 18 approximately 10 nm in the wafer plane. Additionally, the silicon oxy-nitride film is employed as the stopper layer 20, thereby making it possible to make the thickness D2 approximately 1 nm.

In accordance with the second embodiment, by providing the stopper layer 20 for polishing, it is possible to reduce the thickness distribution of the interlayer insulation film 12 and the plug metals 18 in the wafer plane. When the upper insulation film 12b is polished, it is only necessary that the stopper layer 20 should have a polishing rate smaller than that of the upper insulation film 12b. The stopper layer 20 is not limited to the silicon nitride film or the silicon oxy-nitride film.

Nevertheless, in one particular embodiment, the stopper layer 20 is made of an insulation film that includes nitrogen. This reduces the polishing rate of the stopper layer 20, thereby further reducing the thickness distribution of the interlayer insulation film 12 and the plug metals 18.

In addition, in one particular embodiment, the stopper layer 20 includes a silicon oxy-nitride film. Furthermore, in one particular embodiment, the upper insulation film 12b (insulation layer) is polished by using the ceria slurry as the abrasive agent. This can further reduce the polishing rate of the stopper layer 20, and can further reduce the thickness distribution of the interlayer insulation film 12 and the plug metals 18 in the wafer plane.

In one particular embodiment, the upper insulation film 12b includes a silicon oxide film. This can increase the etch selectivity ratio with the stopper layer 20.

In the first and second embodiments, a description has been given of cases where a silicon oxide film is used for the interlayer insulation film 12, the lower interlayer insulation film 12a and the upper insulation film 12b and tungsten is used for the plug metals 18. However, the present invention is not limited thereto. It is only necessary that the interlayer insulation film 12 and the upper insulation film 12b are made of insulation films and the plug metal 18 is made of a metal layer.

Embodiments of the present claimed subject matter generally relates to semiconductor devices. More particularly, embodiments allow semiconductor devices to function with increased efficiency. In one implementation, the claimed subject matter is applicable to flash memory and devices that utilize flash memory. Flash memory is a form of non-volatile memory that can be electrically erased and reprogrammed. As such, flash memory, in general, is a type of electrically erasable programmable read only memory (EEPROM).

Like Electrically Erasable Programmable Read Only Memory (EEPROM), flash memory is nonvolatile and thus can maintain its contents even without power. However, flash memory is not standard EEPROM. Standard EEPROMs are differentiated from flash memory because they can be erased and reprogrammed on an individual byte or word basis while flash memory can be programmed on a byte or word basis, but is generally erased on a block basis. Although standard EEPROMs may appear to be more versatile, their functionality requires two transistors to hold one bit of data. In contrast, flash memory requires only one transistor to hold one bit of data, which results in a lower cost per bit. As flash memory costs far less than EEPROM, it has become the dominant technology wherever a significant amount of non-volatile, solid-state storage is needed.

Examplary applications of flash memory include digital audio players, digital cameras, digital video recorders, and mobile phones. Flash memory is also used in USB flash drives, which are used for general storage and transfer of data between computers. Also, flash memory is gaining popularity in the gaming market, where low-cost fast-loading memory in the order of a few hundred megabytes is required, such as in game cartridges. Additionally, flash memory is applicable to cellular handsets, smartphones, personal digital assistants, set-top boxes, digital video recorders, networking and telecommunication equipments, printers, computer peripherals, automotive nagivation devices, and gaming systems.

As flash memory is a type of non-volatile memory, it does not need power to maintain the information stored in the chip. In addition, flash memory offers fast read access times and better shock resistance than traditional hard disks. These characteristics explain the popularity of flash memory for applications such as storage on battery-powered devices (e.g., cellular phones, mobile phones, IP phones, wireless phones.).

Flash memory stores information in an array of floating gate transistors, called “cells”, each of which traditionally stores one bit of information. However, newer flash memory devices, such as MirrorBit Flash Technology from Spansion Inc., can store more than 1 bit per cell. The MirrorBit cell doubles the intrinsic density of a Flash memory array by storing two physically distinct bits on opposite sides of a memory cell. Each bit serves as a binary bit of data (e.g., either 1 or 0) that is mapped directly to the memory array.

Reading or programming one side of a memory cell occurs independently of whatever data is stored on the opposite side of the cell.

With regards to wireless markets, flash memory that utilizes MirrorBit technology has several key advantages. For example, flash memory that utilizes MirrorBit technology are capable of burst-mode access as fast as 80 MHz, page access times as fast as 25 ns, simultaneous read-write operation for combined code and data storage, and low standby power (e.g., 1 μA).

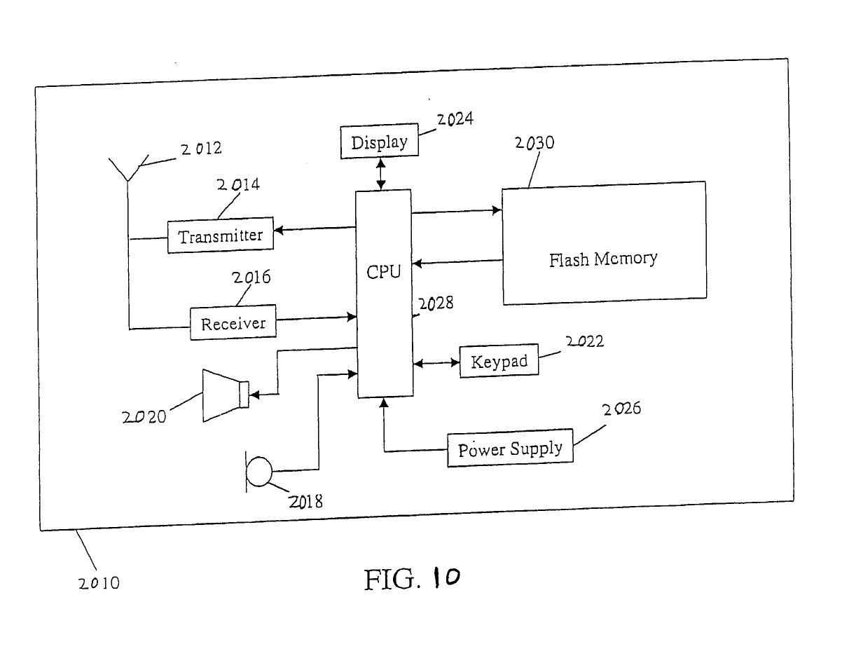

FIG. 10 shows a block diagram of a conventional portable telephone 2010 (a.k.a. cell phone, cellular phone, mobile phone, internet protocol phone, wireless phone, etc.), upon which embodiments can be implemented. The cell phone 2010 includes an antenna 2012 coupled to a transmitter 2014 a receiver 2016, as well as, a microphone 2018, speaker 2020, keypad 2022, and display 2024. The cell phone 2010 also includes a power supply 2026 and a central processing unit (CPU) 2028, which may be an embedded controller, conventional microprocessor, or the like. In addition, the cell phone 2010 includes integrated, flash memory 2030. Flash memory 2030 includes: an interlayer insulation film provided on or above a semiconductor substrate; a silicon oxy-nitride film provided on or above the interlayer insulation film; and a metal layer provided in contact holes formed in the interlayer insulation film, and having a top surface substantially coplanar with a top surface of the silicon oxy-nitride film. In this way, embodiments provide semiconductor devices in which the size of the contact hole and the distance therebetween can be reduced. This improvement can affect various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones.

Flash memory comes in two primary varieties, NOR-type flash and NAND-type flash. While the general memory storage transistor is the same for all flash memory, it is the interconnection of the memory cells that differentiates the designs. In a conventional NOR-type flash memory, the memory cell transistors are connected to the bit lines in a parallel configuration, while in a conventional NAND-type flash memory, the memory cell transistors are connected to the bit lines in series. For this reason, NOR-type flash is sometimes referred to as “parallel flash” and NAND-type flash is referred to as “serial flash.”

Traditionally, portable phone (e.g., cell phone) CPUs have needed only a small amount of integrated NOR-type flash memory to operate. However, as portable phones (e.g., cell phone) have become more complex, offering more features and more services (e.g., voice service, text messaging, camera, ring tones, email, multimedia, mobile TV, MP3, location, productivity software, multiplayer games, calendar, and maps.), flash memory requirements have steadily increased. Thus, a more efficient flash memory will render a portable phone more competitive in the telecommunications market.

Also, as mentioned above, flash memory is applicable to a variety of devices other than portable phones. For instance, flash memory can be utilized in personal digital assistants, set-top boxes, digital video recorders, networking and telecommunication equipments, printers, computer peripherals, automotive navigation devices, and gaming systems.

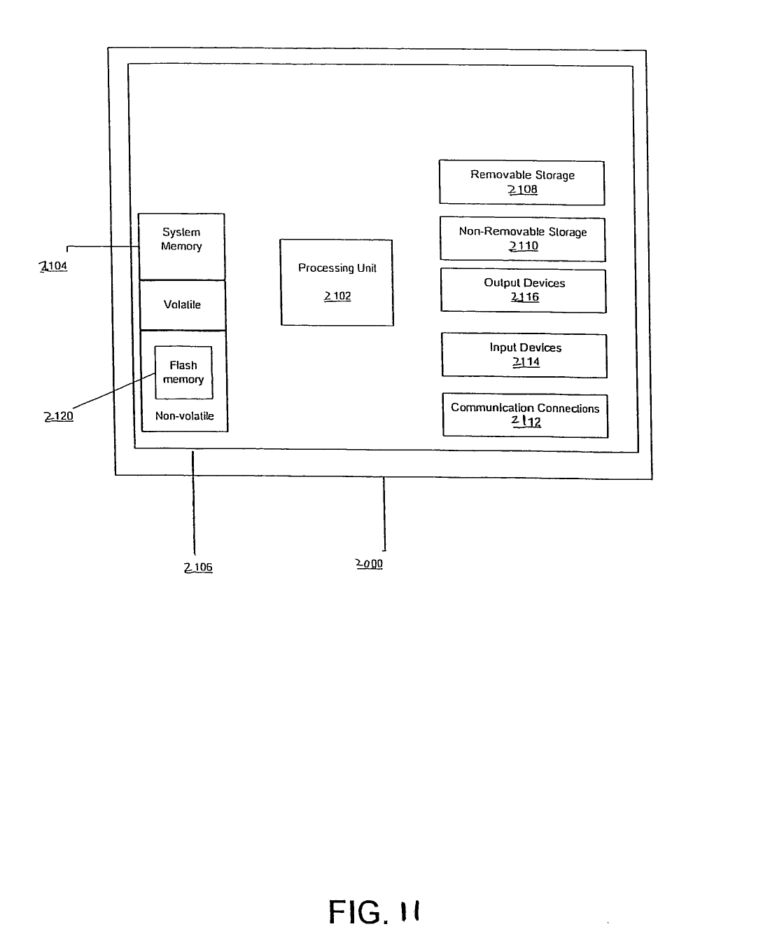

FIG. 11 illustrates a block diagram of a computing device 2100, upon which embodiments of the present claimed subject matter can be implemented. Although computing device 2100 is shown and described in FIG. 11 as having certain numbers and types of elements, the embodiments are not necessarily limited to the exemplary implementation. That is, computing device 2100 can include elements other than those shown, and can include more than one of the elements that are shown. For example, computing device 2100 can include a greater number of processing units than the one (processing unit 2102) shown. Similarly, in another example, computing device 2100 can include additional components not shown in FIG. 11.

Also, it is important to note that the computing device 2100 can be a variety of things. For example, computing device 2100 can be but are not limited to a personal desktop computer, a portable notebook computer, a personal digital assistant (PDA), and a gaming system. Flash memory is especially useful with small-form-factor computing devices such as PDAs and portable gaming devices. Flash memory offers several advantages. In one example, flash memory is able to offer fast read access times while at the same time being able to withstand shocks and bumps better than standard hard disks. This is important as small computing devices are often moved around and encounters frequent physical impacts. Also, flash memory is more able than other types of memory to withstand intense physical pressure and/or heat. And thus, portable computing devices are able to be used in a greater range of environmental variables.

In its most basic configuration, computing device 2100 typically includes at least one processing unit 2102 and memory 2104. Depending on the exact configuration and type of computing device, memory 2104 may be volatile (such as RAM), non-volatile (such as ROM, flash memory, etc.) or some combination of the two. This most basic configuration of computing device 2100 is illustrated in FIG. 11 by line 2106. Additionally, device 2100 may also have additional features/functionality. For example, device 2100 may also include additional storage (removable and/or non-removable) including, but not limited to, magnetic or optical disks or tape. In one example, in the context of a gaming system, the removable storage could a game cartridge receiving component utilized to receive different game cartridges. In another example, in the context of a Digital Video Disc (DVD) recorder, the removable storage is a DVD receiving component utilized to receive and read DVDs. Such additional storage is illustrated in FIG. 11 by removable storage 2108 and non-removable storage 2110. Computer storage media includes volatile and nonvolatile, removable and non-removable media implemented in any method or technology for storage of information such as computer readable instructions, data structures, program modules or other data. Memory 2104, removable storage 2108 and non-removable storage 2110 are all examples of computer storage media. Computer storage media includes, but is not limited to, RAM, ROM, EEPROM, flash memory 2120 or other memory technology, CD-ROM, digital video disks (DVD) or other optical storage, magnetic cassettes, magnetic tape, magnetic disk storage or other magnetic storage devices, or any other medium which can be used to store the desired information and which can accessed by device 2100. Any such computer storage media may be part of device 2100.

In the present embodiment, the flash memory 2120 comprises: an interlayer insulation film provided on or above a semiconductor substrate; a silicon oxy-nitride film provided on or above the interlayer insulation film; and a metal layer provided in contact holes formed in the interlayer insulation film, and having a top surface substantially coplanar with a top surface of the silicon oxy-nitride film. In this way, embodiments provide semiconductor devices in which the size of the contact hole and the distance therebetween can be reduced. This improvement can affect various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones.

Further, in one embodiment, the flash memory 2120 utilizes mirrorbit technology to allow storing of two physically distinct bits on opposite sides of a memory cell.

Device 2100 may also contain communications connection(s) 2112 that allow the device to communicate with other devices. Communications connection(s) 2112 is an example of communication media. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. The term computer readable media as used herein includes both storage media and communication media.

Device 2100 may also have input device(s) 2114 such as keyboard, mouse, pen, voice input device, game input device (e.g., a joy stick, a game control pad, and/or other types of game input device), touch input device, etc. Output device(s) 2116 such as a display (e.g., a computer monitor and/or a projection system), speakers, printer, network peripherals, etc., may also be included. All these devices are well know in the art and need not be discussed at length here.

Aside from mobile phones and portable computing devices, flash memory is also widely used in portable multimedia devices, such as portable music players. As users would desire a portable multimedia device to have as large a storage capacity as possible, an increase in memory density would be advantageous. Also, users would also benefit from reduced memory read time.

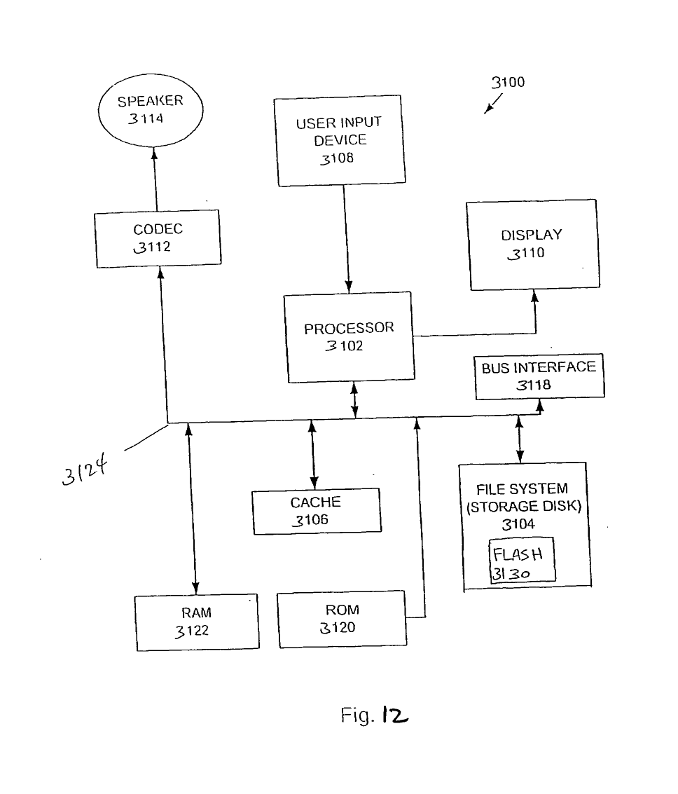

FIG. 12 shows an exemplary portable multimedia device, or media player, 3100 in accordance with an embodiment of the invention. The media player 3100 includes a processor 3102 that pertains to a microprocessor or controller for controlling the overall operation of the media player 3100. The media player 3100 stores media data pertaining to media assets in a file system 3104 and a cache 3106. The file system 3104 is, typically, a storage disk or a plurality of disks. The file system 3104 typically provides high capacity storage capability for the media player 3100. Also, file system 3104 includes flash memory 3130. In the present embodiment, the flash memory 3130 comprises: an interlayer insulation film provided on or above a semiconductor substrate; a silicon oxy-nitride film provided on or above the interlayer insulation film; and a metal layer provided in contact holes formed in the interlayer insulation film, and having a top surface substantially coplanar with a top surface of the silicon oxy-nitride film. In this way, embodiments provide semiconductor devices in which the size of the contact hole and the distance therebetween can be reduced. This improvement can affect various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones.

However, since the access time to the file system 3104 is relatively slow, the media player 3100 can also include a cache 3106. The cache 3106 is, for example, Random-Access Memory (RAM) provided by semiconductor memory. The relative access time to the cache 3106 is substantially shorter than for the file system 3104. However, the cache 3106 does not have the large storage capacity of the file system 3104. Further, the file system 3104, when active, consumes more power than does the cache 3106. The power consumption is particularly important when the media player 3100 is a portable media player that is powered by a battery (not shown). The media player 3100 also includes a RAM 3120 and a Read-Only Memory (ROM) 3122. The ROM 3122 can store programs, utilities or processes to be executed in a non-volatile manner. The RAM 3120 provides volatile data storage, such as for the cache 3106.

The media player 3100 also includes a user input device 3108 that allows a user of the media player 3100 to interact with the media player 3100. For example, the user input device 3108 can take a variety of forms, such as a button, keypad, dial, etc. Still further, the media player 3100 includes a display 3110 (screen display) that can be controlled by the processor 3102 to display information to the user. A data bus 3124 can facilitate data transfer between at least the file system 3104, the cache 3106, the processor 3102, and the CODEC 3110. The media player 3100 also includes a bus interface 3116 that couples to a data link 3118. The data link 3118 allows the media player 3100 to couple to a host computer.

In one embodiment, the media player 3100 serves to store a plurality of media assets (e.g., songs) in the file system 3104. When a user desires to have the media player play a particular media item, a list of available media assets is displayed on the display 3110. Then, using the user input device 3108, a user can select one of the available media assets. The processor 3102, upon receiving a selection of a particular media item, supplies the media data (e.g., audio file) for the particular media item to a coder/decoder (CODEC) 3110. The CODEC 3110 then produces analog output signals for a speaker 3114. The speaker 3114 can be a speaker internal to the media player 3100 or external to the media player 3100. For example, headphones or earphones that connect to the media player 3100 would be considered an external speaker.

For example, in a particular embodiment, the available media assets are arranged in a hierarchical manner based upon a selected number and type of groupings appropriate to the available media assets. For example, in the case where the media player 3100 is an MP3 type media player, the available media assets take the form of MP3 files (each of which corresponds to a digitally encoded song or other audio rendition) stored at least in part in the file system 3104. The available media assets (or in this case, songs) can be grouped in any manner deemed appropriate. In one arrangement, the songs can be arranged hierarchically as a list of music genres at a first level, a list of artists associated with each genre at a second level, a list of albums for each artist listed in the second level at a third level, while at a fourth level a list of songs for each album listed in the third level, and so on.

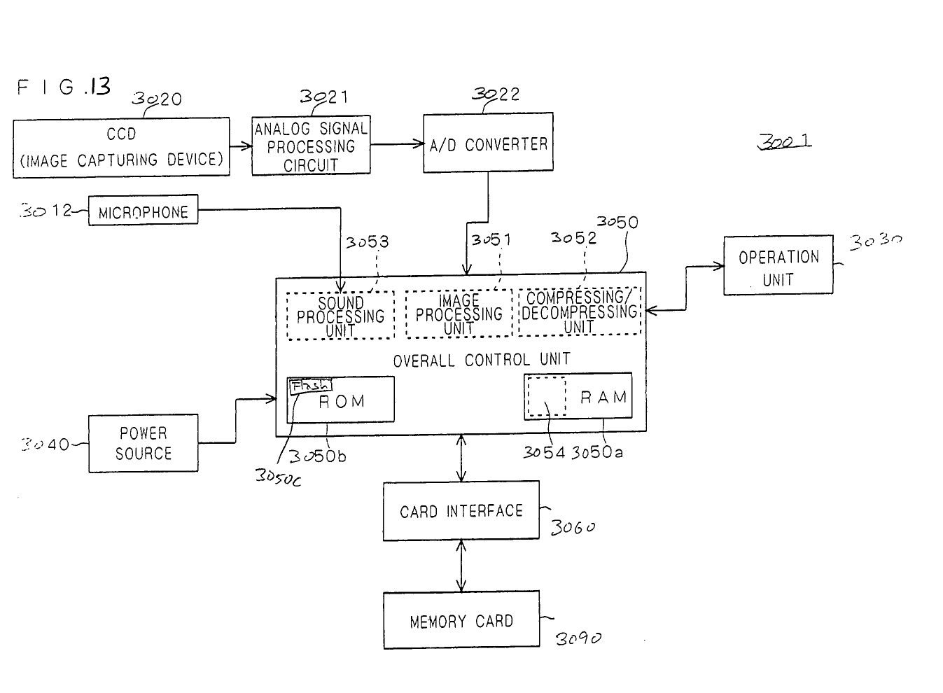

Referring to FIG. 13, the internal configuration of a digital camera 3001 is described. FIG. 13 is a block diagram showing the internal functions of the digital camera 3001. The CCD (image capturing device) 3020 functions as image capturing means for capturing a subject image and generating an electronic image signal and has, for example, 1600 times 1200 pixels. The CCD 3020 photoelectrically converts a light image of the subject formed by the taking lens into image signals (signal made of a signal sequence of pixel signals received by the pixels) of R (red), G (green) and B (blue) pixel by pixel and outputs the image signal.

The image signal obtained from the CCD 3020 is supplied to an analog signal processing circuit 3021. In the analog signal processing circuit 3021, the image signal (analog signal) is subjected to a predetermined analog signal process. The analog signal processing circuit 3021 has a correlated double sampling circuit (CDS) and an automatic gain control circuit (AGC) and adjusts the level of the image signal by performing a process of reducing noise in the image signal by the correlated double sampling circuit and adjusting the gain by the automatic gain control circuit.

An A/D converter 3022 converts each of pixel signals of the image signal into a digital signal of 12 bits. The digital signal obtained by the conversion is temporarily stored as image data in a buffer memory 3054 in a RAM 3050a. The image data stored in the buffer memory 3054 is subjected to WB (white balance) process, gamma correction process, color correction process and the like by an image processing unit 3051 and, after that, the processed signal is subjected to a compressing process or the like by a compressing/decompressing unit 3052.

A sound signal obtained from the microphone 3012 is inputted to a sound processing unit 3053. The sound signal inputted to the sound processing unit 3053 is converted into a digital signal by an A/D converter (not shown) provided in the sound processing unit 3053 and the digital signal is temporarily stored in the buffer memory 3054.

An operation unit is an operation unit that can include a power source button and a shutter release button and is used when the user performs an operation of changing a setting state of the digital camera 3001 and an image capturing operation.

A power source 3040 is a power supply source of the digital camera 3001. The digital camera 3001 is driven by using a secondary battery such as a lithium ion battery as the power source battery BT.

An overall control unit 3050 is constructed by a microcomputer having therein the RAM 3050a and a ROM 3050b. When the microcomputer executes a predetermined program, the overall control unit 3050 functions as a controller for controlling the above-described components in a centralized manner. The overall control unit 3050 also controls, for example, a live view display process and a process of recording data to a memory card. The RAM 3050a is a semiconductor memory (such as DRAM) which can be accessed at high speed and the ROM 3050b takes the form of, for example, an electrically-rewritable nonvolatile semiconductor memory (such as flash ROM 3050c). A flash memory, in one embodiment, includes: an interlayer insulation film provided on or above a semiconductor substrate; a silicon oxy-nitride film provided on or above the interlayer insulation film; and a metal layer provided in contact holes formed in the interlayer insulation film, and having a top surface substantially coplanar with a top surface of the silicon oxy-nitride film. In this way, embodiments provide semiconductor devices in which the size of the contact hole and the distance therebetween can be reduced. This improvement can affect various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones.

An area as a part of the RAM 3050a functions as a buffer area for temporary storing data. This buffer area is referred to as the buffer memory 3054. The buffer memory 3054 temporarily stores image data and sound data.

The overall control unit 3050 has the image processing unit 3051, compressing/decompressing unit 3052 and sound processing unit 3053. The processing units 3051, 3052 and 3053 are function parts realized when the microcomputer executes a predetermined program.

The image processing unit 3051 is a processing unit for performing various digital imaging processes such as WB process and gamma correcting process. The WB process is a process of shifting the level of each of the color components of R, G and B and adjusting color balance. The gamma correcting process is a process of correcting the tone of pixel data. The compressing/decompressing unit 3052 is a processing unit for performing an image data compressing process and an image data decompressing process. As the compressing method, for example, the JPEG method is employed. The sound processing unit 3053 is a processing unit for performing various digital processes on sound data.

A card interface (I/F) 3060 is an interface for writing/reading image data to/from the memory card 3090 inserted into the insertion port in the side face of the digital camera 1. At the time of reading/writing image data from/to the memory card 3090, the process of compressing or decompressing image data is performed according to, for example, the JPEG method in the compressing/decompressing unit 3052, and image data is transmitted/received between the buffer memory 3054 and the memory card 3090 via the card interface 3060. Also at the time of reading/writing sound data, sound data is transmitted/received between the buffer memory 3054 and the memory card 3090 via the card interface 3060.

Further, by using the card interface 3060, the digital camera 3001 transmits/receives data such as an image and sound and, in addition, can load a program which operates on the digital camera 3001. For example, a control program recorded on the memory card 3090 can be loaded into the RAM 3050a or ROM 3050b of the overall control unit 3050. In such a manner, the control program can be updated.

Also by communication with an external device (such as an external computer) via a USB terminal, various data such as an image and sound and a control program can be transmitted/received. For example, various data, a program, and the like recorded on a recording medium (CD-R/RW or CD-ROM) which is set into a reader (optical drive device or the like) of the external computer can be obtained via the USB terminal.

Finally, various aspects of the present invention are summarized in the following.

According to a first aspect of the present invention, there is provided a method of fabricating a semiconductor device including: forming an insulation film on or above a semiconductor substrate; forming contact holes in the insulation film; forming a metal layer in the contact holes; polishing an upper portion of the insulation film below a top surface of an upper portion of the metal layer; and polishing the upper portion of the metal layer.

In the above-described method, forming the contact holes may be forming the contact holes so that the contact holes in the upper portion of the insulation film is wider than the contact holes in a lower portion of the insulation film. It is possible to reduce the size of the contact hole and the distance therebetween.

In the above-described method, forming the insulation film may include forming a lower insulation film, forming a stopper layer above the lower insulation film, and forming an upper insulation film on or above the stopper layer, and polishing the upper portion of the insulation film includes polishing the upper insulation film to the stopper layer, and polishing the metal layer includes polishing the metal layer to the stopper layer. It is possible to reduce the thickness distribution of the lower insulation film and the metal layer in a wafer plane.

In the above-described method, the stopper layer may be the insulation film including nitrogen. It is possible to further reduce the thickness distribution of the lower insulation film and the metal layer in the wafer plane.

In the above-described method, the stopper layer may include a silicon oxy-nitride film. Also, polishing the insulation film includes polishing the insulation film by using ceria slurry. It is possible to further reduce the thickness distribution of the lower insulation film and the metal layer in the wafer plane.

In the above-described method, the upper insulation film may include a silicon oxide film. The selectivity ratio of the stopper layer can be increased.

In the above-described method, the metal layer may include tungsten. Forming the metal layer may include: forming a layer to be the metal layer in the contact holes and on the insulation film; and polishing the layer to be the metal layer to the insulation film.

Although embodiments of the present invention have been shown and described, it would be appreciated by those skilled in the art that changes may be made in these embodiments without departing from the principles and spirit of the invention, the scope of which is defined in the claims and their equivalents.

1. A method of fabricating a semiconductor device comprising:
forming an insulation film on or above a semiconductor substrate;
forming contact holes in the insulation film;
forming a metal layer in the contact holes;
polishing an upper portion of the insulation film below a top surface of an upper portion of the metal layer; and
polishing the upper portion of the metal layer.

2. The method as claimed in claim 1, wherein forming the contact holes is forming the contact holes so that the contact holes in the upper portion of the insulation film is wider than the contact holes in a lower portion of the insulation film.

3. The method as claimed in claim 1, wherein forming the insulation film includes forming a lower insulation film, forming a stopper layer above the lower insulation film, and forming an upper insulation film on or above the stopper layer, and
wherein polishing the upper portion of the insulation film includes polishing the upper insulation film to the stopper layer, and
wherein polishing the metal layer includes polishing the metal layer to the stopper layer.

4. The method as claimed in claim 3, wherein the stopper layer is the insulation film including nitrogen.

5. The method as claimed in claim 4, wherein the stopper layer includes a silicon oxy-nitride film.

6. The method as claimed in claim 1, wherein polishing the insulation film includes polishing the insulation film by using ceria slurry.

7. The method as claimed in claim 3, wherein the upper insulation film includes a silicon oxide film.

8. The method as claimed in claim 1, wherein the metal layer includes tungsten.

9. The method as claimed in claim 1, wherein forming the metal layer includes:
forming a layer to be the metal layer in the contact holes and on the insulation film; and
polishing the layer to be the metal layer to the insulation film.

10. A method of fabricating a semiconductor device comprising:
forming an interlayer insulation film on or above a semiconductor substrate;
forming contact holes so that the contact holes in an upper portion of the interlayer insulation film is wider than the contact holes in a lower portion of the interlayer insulation film;
forming a metal layer in the contact holes; and
polishing the upper portion of the interlayer insulation film and the metal layer, the upper portion being wider than the other portion of the contact holes.

11. A semiconductor device comprising:
an interlayer insulation film provided on or above a semiconductor substrate;
a silicon oxy-nitride film provided on or above the interlayer insulation film; and
a metal layer provided in contact holes formed in the interlayer insulation film, and having a top surface substantially coplanar with a top surface of the silicon oxy-nitride film.

12. A wireless communications device, said wireless communications device comprising:
a flash memory comprising:
an interlayer insulation film provided on or above a semiconductor substrate;
a silicon oxy-nitride film provided on or above the interlayer insulation film; and
a metal layer provided in contact holes formed in the interlayer insulation film, and having a top surface substantially coplanar with a top surface of the silicon oxy-nitride film;
a processor;
a communications component;
a transmitter;
a receiver; and
an antenna connected to the transmitter circuit and the receiver circuit.

13. The wireless communications device of claim 12, wherein said flash memory is NAND flash memory.

14. The wireless communications device of claim 12, wherein said flash memory is NOR flash memory.

15. The wireless communications device of claim 12, wherein said flash memory utilizes mirrorbits technology.

16. A computing device comprising:
a processor;
an input component;
an output component;
a memory comprising:
a volatile memory; and
a flash memory comprising:
an interlayer insulation film provided on or above a semiconductor substrate;
a silicon oxy-nitride film provided on or above the interlayer insulation film; and
a metal layer provided in contact holes formed in the interlayer insulation film, and having a top surface substantially coplanar with a top surface of the silicon oxy-nitride film.

17. The computing device of claim 16, wherein said computing device is a personal computer (PC).

18. The computing device of claim 16, wherein said computing device is a personal digital assistant (PDA).

19. The computing device of claim 16, wherein said computing device is a gaming system.

20. A portable media player comprising:
a processor;
a cache;
a user input component;
a coder-decoder component; and
a memory comprising:
a flash memory comprising:
an interlayer insulation film provided on or above a semiconductor substrate;
a silicon oxy-nitride film provided on or above the interlayer insulation film; and
a metal layer provided in contact holes formed in the interlayer insulation film, and having a top surface substantially coplanar with a top surface of the silicon oxy-nitride film.

21. The portable media player of claim 20, wherein said portable media player is a portable music player.

22. The portable media player of claim 20, wherein said portable media player is a portable video player.

23. An image capturing apparatus comprising:
a sensor for providing image data;
a memory capable of storing said image data, comprising:
an interlayer insulation film provided on or above a semiconductor substrate;
a silicon oxy-nitride film provided on or above the interlayer insulation film; and
a metal layer provided in contact holes formed in the interlayer insulation film, and having a top surface substantially coplanar with a top surface of the silicon oxy-nitride film;
a display operable to display an image from said image data.
